(19) United States
(12) Patent Application Publication
(10) Pub. No.: US 2026/0303108 A1
(43) Pub. Date: Oct. 1, 2026

(54) MEASUREMENT DEVICE WITH CONFIDENCE INDICATOR

(71) Applicant: Analog Devices International Unlimited Company, Limerick (IE)

(72) Inventors: Jonathan Ephraim David Hurwitz, Edinburgh (GB); Naiqian Ren, Limerick (IE); Claire Croke, Aherla (IE); Christoph Kaemmerer, Munchen (DE)

(21) Appl. No.: 19/091,456

(22) Filed: Mar. 26, 2025

(51) Int. Cl. H03M 1/08

(52) U.S. Cl. CPC H03M 1/08

(57) ABSTRACT

A first signal processing circuit is configured to process a first digital signal, for example generated by an analog to digital converter (ADC), to generate a second digital signal based on the first digital output signal. A second signal processing circuit is configured to extract an interference signal from the first digital signal and calculate a confidence indicator based on the interference signal. The confidence indicator is characteristic of a reliability of the second digital signal generated by the first signal processing circuit.

### TECHNICAL FIELD

The present disclosure relates to measurement devices. Particularly, but not exclusively, the present disclosure relates to extracting additional data from signals obtained at and related to measurement devices; more particularly, but not exclusively, the present disclosure relates to generating factors related to the quality of signals generated at measurement devices.

### BACKGROUND

A measurement device, or measurement node, can be coupled to an analog sensor to obtain a discrete digital representation of the physical quantities, such as temperature, pressure, or light, measured by the analog sensor. Such measurement devices typically comprise circuitry to convert the analog signal to a digital representation and to process the digital representation to a transmissible and/or storable form. Processing the digital signal is particularly important in bandwidth limited and/or resource constrained environments where it is may be necessary to minimise the amount of data that needs to be stored, processed, and/or transmitted.

However, each time the digital signal is processed (e.g., through analog to digital conversion, sampling, filtering, compressing, etc.), the information volume of the signal may be reduced such that the information diminishes as it passes through the measurement device. The information lost as a result of processing the signal may contain valuable insights into the operation of the device and the quality of the data generated but can be difficult, if not impossible, to recover or reverse engineer from the output digital signal.

### SUMMARY OF DISCLOSURE

As such, there is a need for improved devices and methods for conveying relevant information from a measurement device or node without significantly increasing the data volume.

In the present disclosure, insights into the quality of data generated by a measurement device are extracted by the measurement device and quantified as a confidence indicator (also referred to herein as a confidence factor). The confidence indicator is provided by the measurement device along with the generated data to enable downstream devices, processes, and systems to determine the quality, reliability, fidelity, and usability of the generated data.

The present disclosure provides a device and method for data confidence factor generation. Measurements related to operation of a measurement device during generation of a digital signal are obtained. A confidence indicator is generated by the measurement device. The confidence indicator is characteristic of the reliability of the digital signal. The digital signal and the associated confidence indicator are then output.

As such, aspects of the present disclosure allow data related to the quality of a digital signal to be generated efficiently in line. This additional data provides insights into the digital signal that cannot be directly derived, or reverse engineered, from the digital signal. As such, downstream devices, processes, and systems can incorporate and/or analyse this additional data to improve the performance and reliability of models, processes, and systems that utilise the digital signal.

Further features and aspects of the disclosure are provided in the appended claims.

### BRIEF DESCRIPTION OF DRAWINGS

The present disclosure will now be described by way of example only with reference to the accompanying drawings in which:

FIG. 1 shows a measurement system according to an aspect of the present disclosure;

FIGS. 2A-2D show example devices, systems, assemblies;

FIGS. 3 and 4 illustrate example systems for generating and using confidence indicators;

FIG. 5 shows a method according to an aspect of the present disclosure; and

FIG. 6 shows an example computing environment.

### DETAILED DESCRIPTION

Analog signals contain an almost infinite volume of information that may be successively diminished by the conversion and processing of analog signals to digital signals. For modern systems that use these digital signals, such as artificial intelligence (AI) and machine learning models, more of this “lost information” becomes relevant. However, as the information is missing, and not directly derivable, from the processed digital signals, it cannot be exploited to improve the performance and operation of downstream systems and processes. The present disclosure is directed to devices and methods for extracting relevant information from the digital signal generation and processing stages, and converting this relevant information to a value (indicator or factor) that characterises the quality, reliability, fidelity, and/or usability of the digital signal. The value conveys additional insights into the operation of the measurement device that can be used to improve the operation, performance, and reliability of the measurement device and systems utilising data generated by the measurement device.

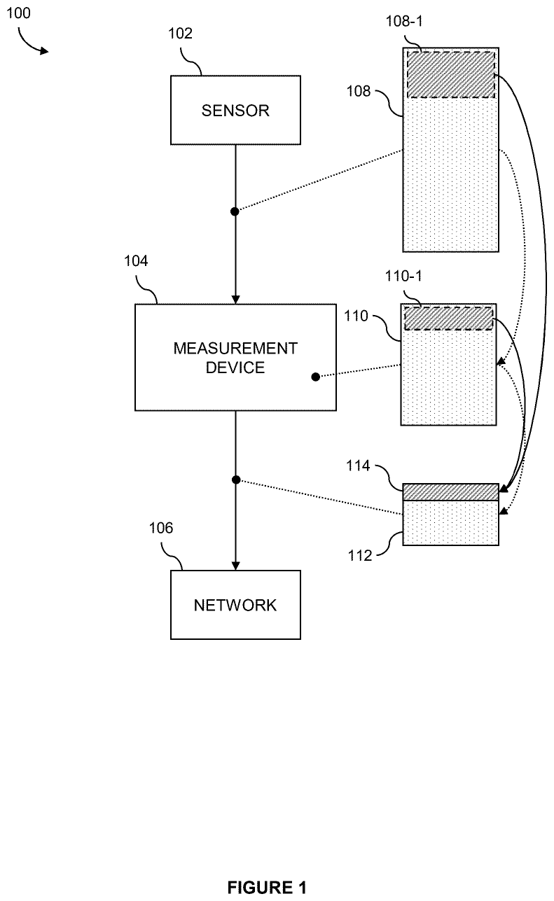

FIG. 1 shows a measurement system 100 according to an aspect of the present disclosure.

The measurement system 100 comprises a sensor 102 and a measurement device 104 communicatively coupled to the sensor 102 and a network 106. In one example implementation, the measurement device 104 itself may comprise the sensor 102, and in another implementation (such as that shown in FIG. 1) the measurement device 104 may be separate devices that are communicatively coupled together. The sensor 102 generates a first signal 108 comprising a first amount of information. The measurement device 104 generates a second signal 110 indicative of the first signal 108. The second signal 110 comprises a second amount of information. The measurement device 104 further generates an output signal 112 that is transmitted along the network 106. The output signal 112 comprises a third amount of information and is generated from the second signal 110. The first signal 108 comprises a first relevant portion 108-1 and the second signal 110 comprises a second relevant portion 110-1. FIG. 1 further shows a confidence indicator 114 generated by the measurement device 104. The confidence indicator 114 is associated with the output signal 112.

The sensor 102 is positioned within an environment and is configured to detect physical phenomena within the environment, such as temperature, light, or pressure, and represent them with an analog signal (e.g., the first signal 108). The analog signal is a continuous electrical signal that varies in amplitude, frequency, and/or phase to represent changes in the physical quantity being measured. For example, the sensor 102 can be a thermocouple operable to measure temperature by generating a voltage proportional to the temperature difference between two junctions, a photodiode operable to detect light intensity and convert it into a corresponding electrical current, or a microphone operable to convert sound waves into electrical signals that vary in amplitude and frequency based on the sound. In one example implementation, the sensor 102 is a low bandwidth sensor configured to measure phenomena that change slowly over time thus requiring only a narrow range of frequencies to capture the information. For example, the sensor 102 can be a temperature sensor or a humidity sensor.

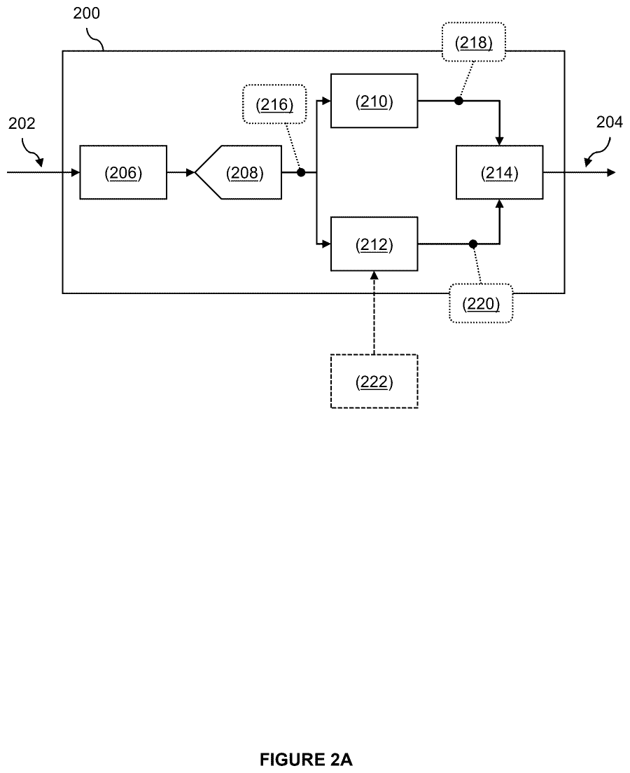

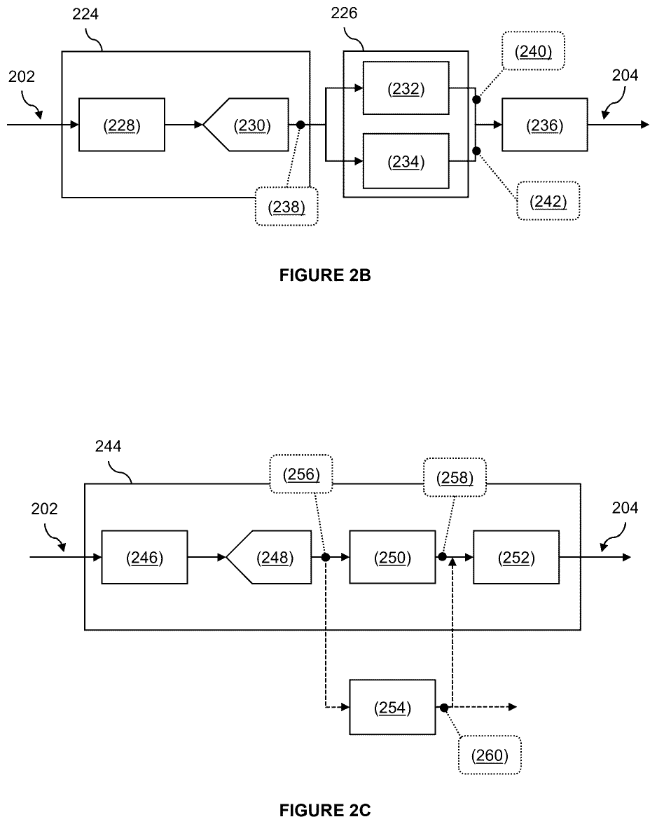

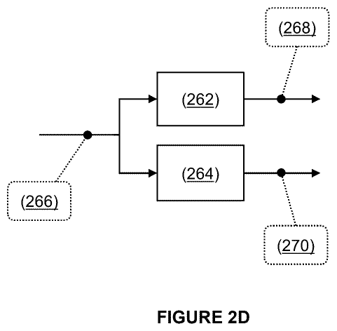

The measurement device 104 (alternatively referred to as an edge measurement node, an edge device, a measurement node, or a data acquisition device) is communicatively coupled to the sensor 102 and comprises circuitry configured to convert or transform the analog signal received from the sensor (e.g., the first signal 108) into a digital signal (e.g., the second signal 110). As described in more detail below in relation to FIG. 2, the measurement device 104 comprises an analog to digital converter (ADC) that transforms the continuous analog signal into a discrete digital signal by sampling the analog input at regular intervals and quantizing the amplitude into a binary values. Any suitable type of ADC may be used, such as a flash ADC, a sigma-delta ADC, a pipelined ADC, an integrating ADC, a successive approximation ADC, etc, the operation of which will be well understood by the skilled person without any further explanation here. The measurement device 104 further comprises signal processing circuitry that processes the digital signal output by the ADC to generate the digital output signal 112 (e.g., by means of filtering, compressing, etc.). That is, the signal processing circuitry transforms the discrete digital signals output by the ADC to a size that is transmissible along the network 106 without overburdening the network 106.

The measurement device 104 comprises an output interface coupled to the network 106. The output interface enables the measurement device 104 to communicate (or transmit) the output signal 112, and other data and/or control signals, to one or more other devices, systems, networks, or users. The output interface thus supports one or more communication protocols such as Ethernet, Wi-Fi, Bluetooth, or the like.

FIG. 1 shows that, as the signal passes through the measurement device 104, its information volume is reduced due to processes like sampling, filtering, signal processing, and/or compression. This is illustrated by the difference in size of the first signal 108 that has a greater amount of information (or information volume) than that of the second signal 110. This reduction in information is due to the operations performed by the measurement device 104 in the analog-to-digital conversion of the first (analog) signal 108 to the second (digital) signal 110. Furthermore, the amount of information in the output (digital) signal 112 is less than that of the second signal 110 due to processing performed by the measurement device 104 to reduce the second signal 110 to a size suitable for transmission along the network 106 (e.g., filtering, compression, etc.). However, the first signal 108 and/or the second signal 110 contain relevant information—such as the first relevant portion 108-1 of the first signal 108 and/or the second relevant portion 110-1 of the second signal 110—that is often lost in the generation of the output signal 112. This relevant information is potentially valuable for downstream processes that utilise the output signal 112 (e.g., machine learning models, data quality analysis, predictive maintenance systems, etc.). The present disclosure is directed to the generation of the confidence indicator 114 that enables insights into the relevant data (e.g., the first relevant portion 108-1 of the first signal 108 and/or the second relevant portion 110-1 of the second signal 110) to be conveyed without significantly increasing the volume of data provided along the network 106.

The confidence indicator 114 (alternatively referred to as a confidence factor, a quality indicator/factor, a meta indicator/factor, or a supplemental data signal) is generated by the measurement device 104 for transmission with the output signal 112 and provides additional information (data/insights) that is not derivable from the output signal 112 without overburdening the network 106. For example, the confidence indicator 114 may be a single value indicative of the amount of power line interference affecting the first signal 108 and/or the second signal 110. As a further example, the confidence indicator 114 may be a binary status value indicative of whether clock jitter in the measurement device 104 has exceeded acceptable limits. The confidence indicator 114 may therefore provide an efficient indicator of the reliability or accuracy of the output signal 112 and/or the operation of the measurement device 104 when generating the output signal 112.

FIG. 2A shows an example measurement device 200 according to an aspect of the present disclosure.

The measurement device 200 is configured to receive an analog input signal 202 (e.g., the first signal 108) and output one or more digital output signals 204. The measurement device 200 comprises an analog front end 206 (such as an amplifier, buffer and/or filter), an ADC 208, a first signal processing circuit 210, a second signal processing circuit 212, and an output interface 214. FIG. 2A further shows an intermediate digital signal 216 (e.g., the second signal 110), a digital output signal 218 (e.g., the output signal 112), a confidence indicator 220, and one or more external devices 222. In one example, the measurement device 200 is the measurement device 104 shown in FIG. 1.

The first signal processing circuit 210, second signal processing circuit and output interface 214 may each be implemented in any suitable way to enable the functionality/operations described below. For example, they may be each be implemented using any suitable combination of a circuit of discrete or integrated components; fixed or programable logic (such as FPGAs and/or ASICs); software comprising instructions for execution on one or more processors, such as microprocessors (such as a microcontroller).

The measurement device 200 receives the analog input signal 202 and the analog front end 206 comprises processing circuitry arranged to process the analog input signal 202 before being converted into digital form by the ADC 208. The analog input signal 202 can be indicative of one or more of: a temperature; a pressure; a humidity ; a light intensity; an audio signal; and/or a motion signal. The analog front end 206 conditions the analog input signal 202 received from a sensor (e.g., a temperature sensor, a pressure sensor, a humidity sensor, etc.) by amplifying, filtering, and/or impedance matching the analog input signal 202. The ADC 208 converts the conditioned analog input signal into the intermediate digital signal 216. The ADC 208 transforms a continuous analog signal into a series of discrete digital samples through the steps of sampling, quantizing, and encoding the signal. During sampling, the analog signal is sampled at regular intervals and the amplitude of the analog signal at each interval is quantised by approximating the sampled value to the nearest value within a finite discrete set of levels. The quantised values are then encoded by converting the values into binary form (i.e., the intermediate digital signal 216).

The first signal processing circuit 210 is coupled to a digital output of the ADC 208 and is configured to process the intermediate digital signal 216 to generate the digital output signal 218 based on the intermediate digital signal 216. The digital output signal 218 is generated by the first signal processing circuit 210 by performing one or more of: filtering the intermediate digital signal 216 (e.g., low-pass, high-pass or band-pass filtering), compressing the intermediate digital signal 216, and/or performing any other suitable type of signal processing on the intermediate digital signal 216. Filtering may be used to remove noise and interference from the intermediate digital signal 216. This process may enhance the quality of the signal by retaining only the most relevant frequency components. For example, a low-pass filter might be used to eliminate high-frequency noise, while a band-pass filter could isolate a specific frequency range of interest. Compression algorithms, such as lossless or lossy compression, may be applied to minimize the amount of data without significantly degrading the signal quality. Lossless compression techniques, like Huffman coding or Run-Length Encoding (RLE), may reduce data size while preserving all original information. Lossy compression methods, such as those used in JPEG or MP3 formats, may achieve higher compression ratios by discarding some less critical information, that may be acceptable depending on the application's requirements. Signal processing may additionally or alternatively include feature extraction, data aggregation, and/or other transformations. For instance, in a measurement device deployed within a sensor network, the signal processing unit might calculate statistical features (mean, variance) or detect specific events (peaks, thresholds) from the filtered and/or compressed data.

The second signal processing circuit 212 is coupled to a digital output of the ADC 208 and is configured to generate the confidence indicator 220. The confidence indicator 220 is a value (e.g., a status bit, an alphanumerical value, a numerical value; and/or a vector of values) characteristic of a reliability of the digital output signal 218 generated by the first signal processing circuit 210. That is, the confidence indicator 220 can be used by a downstream process, system, model, or component to quantify or assess the quality, reliability, fidelity, and/or accuracy of the digital output signal 218. The confidence indicator 220 can also be used to determine the operating status of the measurement device 200.

In one example implementation, the second signal processing circuit 212 generates (calculates) the confidence indicator 220 in response to receiving a request to generate the confidence indicator 220. That is, the confidence indicator 220 is generated on demand or whenever the second signal processing circuit 212 and/or the measurement device 200 are specifically polled.

In general, the second signal processing circuit 212 generates the confidence indicator 220 based on one or more measurements related to operation of the measurement device 200. The one or more measurements can relate to operation of the measurement device 200 during generation of the digital output signal 218. As such, the one or more measurements relate to factors or perturbations that may directly or indirectly affect or influence the quality, reliability, fidelity, and/or accuracy of the digital output signal 218. The confidence indicator 220 is indicative of (characterises or quantifies) these factors or perturbations thereby providing an indicator of the quality, reliability, fidelity and/or accuracy of the digital output signal 218. The one or more measurements used by the second signal processing circuit 212 are obtained (extracted or generated) from the intermediate digital signal 216 by the second signal processing circuit 212 and/or from measurements or signals obtained from the one or more external devices 222.

The one or more measurements include one or more electromagnetic interference measurements extracted from the intermediate digital signal 216 by the second signal processing circuit 212. Electromagnetic interference (EMI) in the intermediate digital signal 216 corresponds to the interference resulting from unwanted electromagnetic signals (e.g., from power lines, radio transmitters, and/or other electronic devices) that affect the quality, accuracy, reliability, and/or integrity of the intermediate digital signal 216 and/or the digital output signal 218. An EMI measurement is an example of an interference signal that is obtained by applying a transform, such as a Fast Fourier Transform (FFT), to the intermediate digital signal 216. The transform reveals the different frequency components in the intermediate digital signal 216. The output of the transform is analysed to identify the frequency components that correspond to known sources of EMI (e.g., power lines, radio transmitters, other electronic devices, etc.).

The one or more EMI measurements include one or more power line interference measurements extracted from the intermediate digital signal 216. A power line interference measurement quantifies the level of interference within the intermediate digital signal 216 and/or the digital output signal 218 resulting from power line noise. The power line interference measurement(s) are generated by measuring the amplitude of the frequency components in the FFT at specific frequencies associated with power line interference (e.g., 50 Hz or 60 Hz and one or more of their harmonics 100 Hz or 120 Hz, etc) and/or by calculating the power of the power line interference by integrating the power spectral density (PSD) over the specific frequencies associated with power line interference.

The one or more EMI measurements may include one or more out-of-band interference measurements extracted from the intermediate digital signal 216. An out-of-band interference measurement quantifies the level of unwanted signals (noise) that fall outside the designated frequency band of interest but still affect/influence the quality or reliability of the intermediate digital signal 216 and/or the digital output signal 218. An out-of-band interference measurement may be obtained by applying a transform, such as the FFT, to the intermediate digital signal 216 and identifying the frequency components of the transform that fall outside of the designated frequency band of interest (i.e., the out-of-band frequencies). The skilled person will appreciate that the frequency band of interest will differ depending on application. The out-of-band interference measurement(s) may be determined by measuring the amplitude of the out-of-band frequencies and/or by integrating the power spectral density (PSD) over the out-of-band frequency range to determine the power of the out-of-band interference.

The one or more measurements obtained by the second signal processing circuit 212 may also include a DC offset in the AC measurement (i.e., a DC offset measurement) that is represented by the intermediate digital signal 216. The intermedial digital signal 216 may include both an AC component (the varying part of the signal) and a DC offset (the constant part) that can affect the accuracy of the intermediate digital signal 216 and/or the digital output signal 218. The DC offset in an AC measurement is an example of an interference signal corresponding to a constant voltage component added to an AC signal, shifting its baseline away from zero. To determine the DC offset, samples of the intermediate digital signal 216 may be collected over a predefined time period (e.g., 10 s, 20 s, 30 s, 60 s, 120 s, etc.) and the average (e.g., mean) of the collected samples may be calculated. The average of the collected samples may be recorded as the DC offset in AC measurement because the AC components of the intermediate digital signal 216 should average out to zero, or approximately zero, over a complete cycle.

The one or more measurements obtained by the second signal processing circuit 212 may additionally or alternatively include an electrical overstress measurement. Electrical overstress (EOS) may occur when an electrical device is subjected to voltage, current, or power levels that exceed its maximum rated limits (e.g., due to power surges, electrostatic discharge, or other sources of electrical stress). The second signal processing circuit 212 may measure EOS directly from test points within the measurement device 200 such as power inputs, signal lines, and/or ground connections or indirectly by obtaining EOS measurements from the one or more external devices 222 (e.g., an oscilloscope or data logger coupled to the measurement device 200 or power lines/inputs, signal lines, etc. coupled to the measurement device 200). The electrical overstress measurement can be an indicator value or status bit that is set when the voltage, current, or power levels exceed a maximum rated limit or threshold. Alternatively, the electrical overstress measurement can be a voltage or current measurement recorded when the voltage, current, or power level exceed a maximum rated limit or threshold.

The one or more measurements obtained by the second signal processing circuit 212 may additionally or alternatively include one or more high frequency interference on power supply rails measurements. A high frequency interference on power supply rails measurement may quantify the unwanted high-frequency noise that is superimposed on the DC power supply lines. This interference can originate from various sources, such as switching regulators, digital circuits, or external electromagnetic sources. The second signal processing circuit 212 and/or the one or more external devices 222 may be arranged to sample the voltage on the power supply rails of the measurement device 200 (e.g., using an oscilloscope or spectrum analyser) and identify high-frequency components that are not part of the desired DC signal from a frequency analysis of the sampled voltage. The amplitude and/or power of the high-frequency components may be used to determine the high frequency interference on power supply rails measurement(s).

The one or more measurements obtained by the second signal processing circuit 212 may additionally or alternatively include an input common mode voltage change measurement. An input common mode voltage change measurement refers to the assessment of how the common mode voltage at the input of a circuit (e.g., at the analog front end 206) varies over time. The common mode voltage is the average of the voltages present on the input terminals relative to a common reference, such as ground. The second signal processing circuit 212 and/or the one or more external devices 222 may be arranged to measure the voltages at the input terminals to the measurement device 200 (e.g., the input terminals to the analog front end 206). The input voltages—Vᵢₙ₊,—may be measured relative to a common reference, such as ground, and the common mode voltage may be measured as V_{CM}=(Vᵢₙ₊+Vᵢₙ₋)/2. The common mode voltage may be monitored continuously or at regular intervals (e.g., every 1 s, 5 s, 10 s, 30 s, etc.) and the input common mode voltage change measurement calculated as the change in common mode voltage in relation to a previous input common mode voltage measurement (e.g., immediately prior measurement or an average of prior measurements over a predefined window such as the prior 5, 10, 20, etc. measurements).

The one or more measurements obtained by the second signal processing circuit 212 may additionally or alternatively include a supply voltage fluctuation measurement. The supply voltage fluctuation measurement may quantify the variations in the magnitude of the supply voltage to the measurement device 200 over time. These fluctuations can be repetitive or random and are often caused by changes in the load on the power system, such as the switching on and off of large electrical devices. The second signal processing circuit 212 and/or the one or more external devices 222 may be arranged to measure the voltage levels at the power supply rails of the measurement device 200. The voltage levels may be monitored and recorded at regular intervals (e.g., every 1 s, 5 s, 10 s, 30 s, etc.) and the recorded levels used to generate the supply voltage fluctuation measurement. For example, the supply voltage fluctuation measurement may be the average voltage level recorded over a prior period (e.g., the previous 30 s, 60 s, 5m, 10m, etc.) or may be the difference between the current recorded level and a baseline voltage level (e.g., the expected voltage level or the average voltage over a prior period).

The one or more measurements obtained by the second signal processing circuit 212 may additionally or alternatively include one or more clock frequency fluctuation measurements. Clock frequency fluctuation (or clock jitter) refers to the variations in the timing of clock pulses from their ideal positions and is indicative of the stability of the clock source. In the context of the measurement device 200, frequency fluctuation in the clock signal used by the ADC 208 can cause deviations in the sampling points of the ADC 208. The second signal processing circuit 212 and/or the one or more external devices 222 may be arranged to capture the clock signal driving the ADC 208. The clock signal captured over a predefined period (e.g., 10 s, 20 s, 30 s, 1m, 5m, 10m, etc.) may then be analysed to determine the clock frequency fluctuation measurement. That is, timing variations of the clock edges during the predefined period may be recorded by calculating metrics such as peak-to-peak jitter, root mean square (RMS) jitter, and period jitter. The one or more clock frequency fluctuation measurements may be calculated from the metrics determined during the predefined period (e.g., by calculating the average of one or more of the metrics, or standard deviation/variance of one or more of the metrics, etc.).

The one or more measurements obtained by the second signal processing circuit 212 may additionally or alternatively include one or more clock jitter level measurements. Unlike clock frequency fluctuation measurements, that capture the change in clock jitter over time, clock jitter level may measure the short-term variations in the timing of clock edges from their ideal positions. Jitter quantifies the deviations in the clock signal's period from cycle to cycle, that can be caused by noise, power supply variations, or interference. The second signal processing circuit 212 and/or the one or more external devices 222 may be arranged to capture the clock signal driving the ADC 208 and calculate metrics such as peak-to-peak jitter, root mean square (RMS) jitter, and period jitter on a cycle-by-cycle basis. The one or more clock jitter level measurements may be calculated from the metrics (e.g., by calculating the average of one or more of the metrics, or standard deviation/variance of one or more of the metrics, etc.).

The one or more measurements obtained by the second signal processing circuit 212 may additionally or alternatively include a reference voltage fluctuation measurement. In examples where the measurement device 200 is coupled to a voltage reference device (such as a band-gap voltage reference), the second signal processing circuit 210 and/or the one or more external devices 222 may be arranged to record the voltage output of the voltage reference device and analyse the recorded data to identify the magnitude and frequency of the voltage fluctuations (e.g., based on voltage readings obtained over a predefined period such as 10 s, 20 s, 30 s, 1m, 5m, 10m, etc.).

The one or more measurements obtained by the second signal processing circuit 212 may additionally or alternatively include one or more external or environmental measurements such as a temperature measurement, a humidity measurement, a mechanical stress measurement, and/or a vibration measurement. The external or environmental measurements may be obtained by one or more sensors coupled to the second signal processing circuit 212 and/or the one or more external devices 222 (e.g., a temperature sensor, a humidity sensor, a piezoelectric sensor, an accelerometer, etc.). The one or more sensors may be arranged to monitor the environment in which the measurement device 200 operates and thereby provide data relevant to the operation and performance of the measurement device 200. An external or environmental measurement may be calculated from signals or data obtained from a corresponding sensor (e.g., a mechanical stress measurement obtained from a piezoelectric sensor). An external or environmental measurement can be the raw signal value or data obtained from a sensor at a given time point. Alternatively, an external or environmental measurement can be calculated from signal values or data obtained from a sensor over a predefined period (e.g., the prior 1 s, 5 s, 10 s, 30 s, 1m, 5m, etc.). For example, the average or standard deviation in temperature over a 30 s time period or the maximum vibration recorded over a 5-minute period.

The one or more measurements obtained by the second signal processing circuit 212 may additionally or alternatively include one or more mission profile measurements that comprise one or more external or environmental measurements recorded over a period of time (e.g., 1 week, 1 month, 1 year, or longer).

The confidence indicator 220 may be calculated by the second signal processing circuit 212 using the one or more measurements. The confidence indicator 220 is a single value that can be understood as quantifying or indicating the confidence that can be placed in the quality, reliability, fidelity, and/or accuracy of the digital output signal 218. The confidence indicator 220 can correspond directly to one of the one or more measurements (e.g., the amplitude of the 50 Hz frequency component so that the confidence indicator 220 is inversely correlated with the power line interference within the digital output signal 218). In one example, the one or more measurements are scaled, normalised, or otherwise transformed to generate the confidence indicator 220. Alternatively, the confidence indicator 220 can be a binary indicator value that is set (e.g., takes the value 1) if the one or more measurements satisfy a specific condition and is unset (e.g., takes the value 0) if not. For example, if the EOS measurement does not exceed a maximum rated limit or threshold then the confidence indicator is set to 1, indicating that the digital output signal 218 is reliable, and is set to 0 if the EOS measurement does exceed the maximum rated limit or threshold.

In one example, the confidence indicator 220 is indicative of multiple measurements combined and represented as a single value. For example, the second signal processing circuit 212 may combine multiple external or environmental measurements to generate a confidence indicator 220 that is indicative of the overall environmental operating conditions of the measurement device 200. This could be represented as a single binary value (e.g., that takes the value 1 if the external or environmental measurements are within expected ranges) or a single real value representing the extent to which the external or environmental measurements deviate from their expected values or ranges (e.g., the L1-norm or L2-norm of the actual measurements from their expected values).

In one example, the second signal processing circuit 212 may generate multiple confidence indicators (as above) to indicate different aspects of the digital output signal 218 (e.g., two confidence indicators, three confidence indicators, etc.). These confidence indicators can be sent individually or as a vector of values.

In one example, the second signal processing circuit 212 may perform operations to compare the confidence indicator 220 to a predefined threshold and, if the confidence indicator 220 meets the predefined threshold, trigger an interrupt. Alternatively, one or more measurements may be compared to one or more predefined thresholds and, if the one or more measurements meet the predefined threshold, then an interrupt is triggered. The interrupt can be sent to external devices and/or processes via the output interface 214 by means of the confidence indicator 220 or by a separate signal (not shown). Optionally, the interrupt may alter operation of the measurement device 200 (e.g., halt normal operation of the measurement device 200 and/or change the state of the measurement device 200). As an example, if the confidence indicator 220 is generated from temperature measurements and is set to 1 if the temperature exceeds normal operating limits, then when the confidence indicator 220 transitions to the value 1 (i.e., meets the predefined threshold of 1), an interrupt is triggered that stops operation of the measurement device 200 (and/or other devices that receive the interrupt) until the temperature returns to within normal operating limits and the confidence indicator 220 transitions to the value 0.

The output interface 214 is configured to output the digital output signal 218 and the confidence indicator 220. As described in more detail below, the confidence indicator 220 can then be used by a downstream process or task (e.g., a machine learning model or training process) to provide additional contextual insights into the confidence that can be placed on the digital output signal 218.

The output interface 214 can be configured to adjust delivery of the confidence indicator 220. For example, the confidence indicator can be sent with every measurement data sample (e.g., with the digital output signal 218 or with the intermediate digital signal 216), with every N measurement data samples, or the confidence indicator 220 can be generated on demand (e.g., in response to the measurement device 200 receiving a request to generate and send a confidence indicator).

FIG. 2B shows a measurement system/assembly according to an example implementation.

The measurement assembly comprises an input device 224 and a signal processing device 226. The input device 224 comprises an analog front end 228 and an ADC 230. The signal processing device 226 comprises a first signal processing circuit 232 and a second signal processing circuit 234. The measurement assembly further comprises an output interface 236. The input device 224 is arranged to receive an analog input signal 202 and generate an intermediate digital signal 238 that is passed to the signal processing device 226. The first signal processing circuit 232 generates a digital output signal 240 based on the intermediate digital signal 238 and the second signal processing circuit 234 generates a confidence indicator 242. In one example, the second signal processing circuit 234 is coupled to one or more external devices (not shown). The output interface 236 is arranged to output one or more digital output signals 204 that include the digital output signal 240 and the confidence indicator 220.

In the example shown in FIG. 2B, the input device 224, the signal processing device 226, and the output interface 236 are separate devices communicatively coupled (e.g., via one or more communication paths or networks). As such, the signal processing device 226 is arranged to receive and send signals to/from the other devices but otherwise operate independently of these devices.

The functionality of, and operations performed by, the analog front end 228, the ADC 230, the first signal processing circuit 232, the second signal processing circuit 234, and the output interface 236 can be the same as the functionality of, and operations performed by, the analog front end 206, the ADC 208, the first signal processing circuit 210, the second signal processing circuit 212, and the output interface 214 shown in FIG. 2A. Accordingly, the description of the components provided above in relation to FIG. 2A may be used to understand the corresponding components of the measurement assembly of FIG. 2B.

FIG. 2C shows a measurement system/assembly according to a further example implementation.

The measurement assembly comprises a measurement device 244 comprising an analog front end 246, an ADC 248, a signal processing circuit 250, and an output interface 252. The measurement assembly further comprises a signal processing device 254 comprising signal processing circuitry. The measurement device 244 is arranged to receive an analog input signal 202 and the ADC 248 is arranged to generate an intermediate digital signal 256 that is passed to the signal processing circuit 250. The signal processing circuit 250 generates a digital output signal 258 based on the intermediate digital signal 256. The output interface 252 is arranged to output one or more digital output signals 204 that include the digital output signal 258. The signal processing device 254 generates a confidence indicator 260 that can be directly outputted from the signal processing device 254 (e.g., via an internal output interface) or output via the output interface 252 of the measurement device 244. The signal processing device 254 can generate the confidence indicator 260 from the intermediate digital signal 256 and/or from signals/data received from one or more external devices (not shown).

In the embodiment shown in FIG. 2C, the measurement device 244 and the signal processing device 254 are separate devices that can be communicatively coupled (e.g., via one or more communication paths or networks). As such, the signal processing device 254 is arranged to receive and send signals to/from the measurement device 244 but otherwise operates independently of this device.

The functionality of, and operations performed by, the analog front end 246, the ADC 248, the signal processing circuit 250, the signal processing circuitry of the signal processing device 254, and the output interface 252 can be the same as the functionality of, and operations performed by, the analog front end 206, the ADC 208, the first signal processing circuit 210, the second signal processing circuit 212, and the output interface 214 shown in FIG. 2A. Accordingly, the description of the components provided above in relation to FIG. 2A may be used to understand the corresponding components of the measurement assembly of FIG. 2C.

FIG. 2D shows components of a device according to a further example implementation.

FIG. 2D shows a first signal processing circuit 262 and a second signal processing circuit 264 that are both arranged to receive a first digital signal 266. The first signal processing circuit 262 generates a second digital signal 268 that is dependent on the first digital signal 266. The second signal processing circuit 264 generate a confidence indicator 270 that is indicative of the quality of the second digital signal 268.

The components shown in FIG. 2D may form part of a device such as a digital signal processors, a digital signal controller, an edge device (e.g., a measurement device as described above), or any other suitable device which processes a digital signal. For example, the first digital signal 266 may be a digital signal of a biomedical sensor (e.g., electrocardiogram, electroencephalogram, etc.) and the second digital signal 268 may be a processed signal used for diagnosis/monitoring that has been processed by the first signal processing circuit 262. As another example, the first digital signal 266 may be a digital audio stream and the first signal processing circuit 262 may perform noise reduction, equalization, and compression to generate the second digital signal 268 which is an enhanced version of the first digital signal 266 used for playback or further processing. In yet a further example, the first digital signal 266 may be a digital data stream (e.g., received from a communication channel) and the first signal processing circuit 262 may perform error correction on the first digital signal 266 to generate the second digital signal 268 for transmission or reception.

The confidence indicator 270 is generated by the second signal processing circuit 264 to encode or quantity the quality, fidelity, reliability, and usability of the second digital signal 268. For example, the confidence indicator 270 may be indicative of an amount of EMI interference within the first digital signal 266 thereby enabling downstream processes to determine the level of interference within the source signal as opposed to interference introduced by subsequent processes (e.g., transmission, further processing, etc.).

The functionality of, and operations performed by, the first signal processing circuit 262 and the second signal processing circuit 264 can be the same as the functionality of, and operations performed by, the first signal processing circuit 210 and the second signal processing circuit 212 shown in FIG. 2A. Accordingly, the description of the components provided above in relation to FIG. 2A may be used to understand the corresponding components of FIG. 2D.

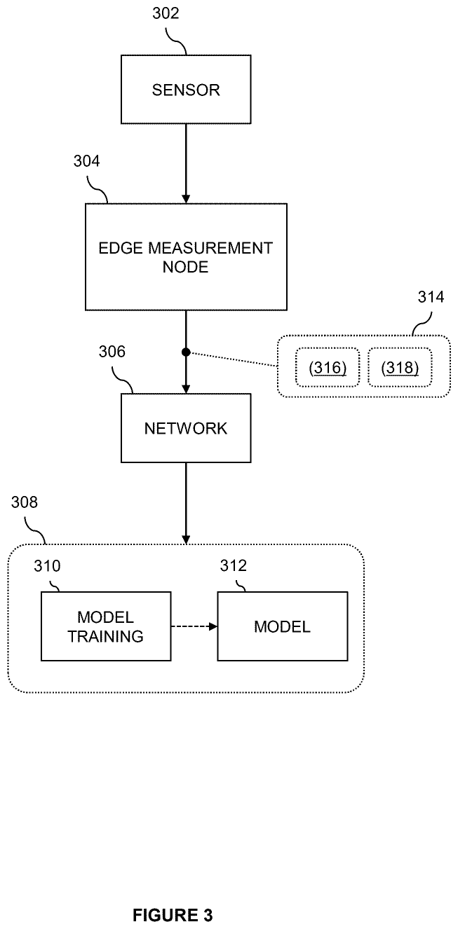

FIG. 3 shows an example system for generating and using confidence indicators.

FIG. 3 shows a sensor 302, an edge measurement node 304, a network 306, and an external system 308 comprising a model training device 310 and a model 312. FIG. 3 further shows a stream of data 314 comprising output data 316 and associated confidence indicators 318.

In this example, the sensor 302 is an analog temperature sensor arranged to provide current or voltage output proportional to the absolute temperature. The skilled person will appreciate that whilst the example shown in FIG. 3 is directed to temperature sensing, the functionality and operations described in relation to FIG. 3 are not limited as such. Indeed, any suitable sensor or sensing technology may be used and integrated (e.g., pressure sensors, humidity sensors, motion sensors, etc.). The sensor 302 is placed within an environment and coupled to the edge measurement node 304 such that the edge measurement node 304 receives temperature readings (current or voltage output of the sensor 302) indicative of the temperature of the environment. In the example shown in FIG. 3, the environment is an industrial plant (e.g., a food processing plant) where the sensor 302 is arranged to measure the temperature of an industrial process as part of a control line related to the industrial process (e.g., a temperature sensor used to monitor the storage conditions of raw materials used in the food processing plant).

The edge measurement node 304 is arranged to convert the analog temperature measurements obtained from the sensor 302 to the output data 316 and associated confidence indicators 318. That is, the edge measurement node 304 receives a stream of analog temperature measurements and generates the stream of data 314 which is a digital signal comprising the output data 316 (i.e., the digital data representative of the analog temperature measurements) and the associated confidence indicators 318 (i.e., values indicative of the quality/reliability of the output data 316). The edge measurement node 304 corresponds to any one of the devices described above in relation to FIGS. 2A-2C.

The stream of data 314 is transmitted across the network 306 to the external system 308. In the example shown in FIG. 3, the external system 308 is separate from the measurement system (e.g., the sensor 302 and the edge measurement node 304) but is a part of the same industrial site as the measurement system. In this example, the network 306 is a local area network (LAN) such that the stream of data 314 is transmitted using a communication protocol such as Ethernet, Wi-Fi, although it may alternatively be any other suitable type of data network.

In this example, the external system 308 is a prediction system used to generate and execute prediction models using measurement data obtained from control lines related to the industrial process. That is, the model training device 310 and the model 312 use the output data 316 and the associated confidence indicators 318 to generate prediction models and predictions respectively. Because the associated confidence indicators 318 characterise the quality of the data generated by the edge measurement node 304, they can be used to improve the accuracy and usability of prediction models generated using the output data 316.

For example, the model training device 310 may be used to generate a prediction model (e.g., the model 312) that predicts the temperature of the industrial process at a future time point based on the temperature measurements over a window prior to the future time point (e.g., predict the temperature at time t+1 based on the temperature readings during the window [t−n, t] ). Example prediction models for such forecasting include autoregressive integrated moving average (ARIMA) models, seasonal ARIMA models, support vector regression (SVR) models, vector autoregression (VAR) models, and the like. To obtain training data for training such models, the data stream from the edge measurement node 304 may be obtained over a period of time (e.g., 1 day, 1 week, 1 month, etc.) and split into a data set of observations (e.g., a sequence of data in the window [t−n, t] ) and target (e.g., the temperature at time t+1) for varying values of t. In this example, n=30 though any suitable window size may be used. Each observation and target may be accompanied by a corresponding confidence indicator value indicating the confidence that can be placed in that observation and target during model training.

In this example, the confidence indicator is generated based on the level of power line interference such that the confidence indicator is indicative of the level of interference resulting from power line noise within the digital output signals within the window of observations. A high confidence indicator value indicates that a high level of confidence can be placed in the observations (e.g., a low level of power line interference) whilst a low confidence indicator value indicates that a low level of confidence can be placed in the observations (e.g., a high level of power line interference). The model training device 310 may use the confidence indicator values to weight the corresponding observations so that the temperature readings that have a low level of interference are weighted more highly than those with a high level of interference. This reduces the influence of more noisy temperature measurements thereby enabling the model training device 310 to generate a more robust and accurate prediction model.

As a further example, a model (such as the model 312 or any other suitable prediction model) may utilize confidence indicators (e.g., the associated confidence indicators 318) independently of the output data 316. For example, if there is a correlation between an outcome or event (e.g., mechanical failure of a device or system monitored by the edge measurement node 304) and the level of power line interference experienced by the sensor 302 and/or the edge measurement node 304, then the model 312 may directly predict the outcome or event (e.g., mechanical failure) from the associated confidence indicators 318. Such models can be deployed in parallel to other models which utilize the output data 316 (such as the example model described above) to provide a robust monitoring and data capture system.

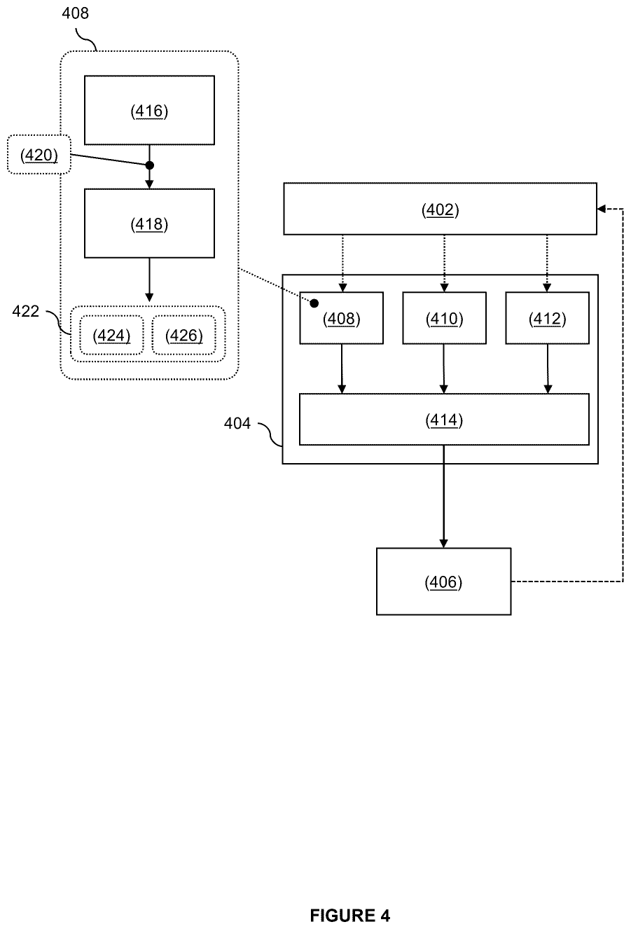

FIG. 4 shows another example system for generating and using confidence indicators.

FIG. 4 shows a system 402 monitored by a monitoring device 404 that is coupled to a control device 406. The control device 406 is arranged to receive data from the monitoring device 404 and adjust operation of the system 402 based on the received data. The monitoring device 404 comprises a first measurement line 408, a second measurement line 410, and a third measurement line 412. Each of the measurement lines are coupled to an output interface 414. The first measurement line 408 comprises a sensor 416 and a measurement node 418. The sensor 416 generates an analog measurement signal 420 and the measurement node 418 generates digital output data 422 related to the analog measurement signal 420. The digital output data 422 comprises a digital output signal 424 and a confidence indicator 426. The output interface 414 outputs the data received from each measurement line.

In the example shown in FIG. 4, the system 402 is a magnetic resonance imaging (MRI) system designed to produce detailed images of the body's internal structures. A powerful superconducting magnet, housed within a large cylindrical structure, generates a strong and uniform magnetic field for imaging. Surrounding the magnet are gradient coils that create variable magnetic fields, allowing the machine to focus on specific areas of the body. Additionally, radiofrequency (RF) coils transmit radio waves into the body and receive the signals emitted by hydrogen atoms in the tissues. A patient lies on a motorized table that slides into the bore, or central opening, of the magnet. The signals received from the RF coils are processed and reconstructed into detailed images of the internal structures of the patient. To maintain the superconducting magnet at the extremely low temperatures required for efficient operation, a cooling system, often using liquid helium, is employed.

The monitoring device 404 comprises sensors that continuously or near continuously monitor the MRI system. The sensors are arranged within measurement lines that obtain sensor readings and generate associated digital signals and accompanying confidence indicators. The first measurement line 408 may be arranged to obtain temperature readings of the superconducting magnets of the MRI system. The second measurement line 410 may be arranged to obtain measurements related to the electrical current provided to the MRI system. The third measurement line 412 may be arranged to obtain vibration measurements that could indicate mechanical issues within the MRI system.

As shown by the components of the first measurement line 408, each measurement line comprises a measurement node (e.g., the measurement node 418) that generates a digital output signal and a confidence indicator (e.g., the digital output signal 424 and the confidence indicator 426). As such, the output interface 414 receives the digital output data from each measurement line (e.g., the temperature output data, the electrical current output data, and the vibration output data) and transmits the data along a communication path to the control device 406.

The control device 406 may utilise the digital output signals and associated confidence indicators of the digital output data received from the measurement lines for sensor diagnostics and/or diagnostics of the measurement nodes of the monitoring device 404. For example, the confidence indicator for one or more of the measurement lines (e.g., the confidence indicator 426) may represent the amount of electromagnetic interference (EMI) in the digital output signal (e.g., the digital output signal 424). Misconnection of the sensor, wear/tear of the cabling, damage to the equipment shielding, and improper grounding can all cause higher than usual EMI magnitude and/or higher power in the harmonics. As described in detail above in relation to FIG. 2, the measurement node (e.g., the measurement node 418) may convert the magnitude of the EMI interference into a confidence factor that is a quantitative value indicative of the amount of EMI interference within the accompanying digital output data. The control device 406 may comprise processing circuitry and/or software that monitors the received confidence factors over time to detect issues related to misconnection of the sensor, cable wear, etc. For example, if the level of EMI interference for one of the measurement lines is above a predefined threshold level for a continuous period of time (e.g., 1 hour, 1 day, 1 week, etc.) then the control device 406 may issue an alert that there is a potential issue with the measurement line that may require servicing or repair.

The control device 406 may additionally or alternatively utilise the digital output signals and associated confidence indicators of the digital output data received from the measurement lines for condition based monitoring and predictive maintenance of the system 402. Condition-Based Monitoring (CBM) is a maintenance strategy that involves continuously or periodically monitoring the condition of machinery, equipment, or systems to assess their performance and detect signs of wear, damage, or failure. Instead of adhering to a fixed maintenance schedule, CBM relies on real-time data to determine when maintenance is needed, enabling timely interventions before significant issues occur.

As stated above, the measurement lines may be arranged to monitor critical components of the MRI system. The control device 406 may comprise one or more prediction models that are used to predict potential failures based on the data received from the measurement lines. For example, the control device 406 may comprise a model that predicts issues with the cooling system of the MRI system based on temperature sensor readings obtained from the first measurement line 408. As a further example, the control device 406 may comprise a rule-based model that predicts an operating state of the MRI system based on the sensor readings obtained from all measurement lines. The confidence factor, or factors, obtained from the measurement lines can serve as an additional input to such prediction models. If one or more parameters contributing to the confidence factor are strongly correlated with a specific signature of a target fault, the confidence factor can be utilized to predict the occurrence of that fault.

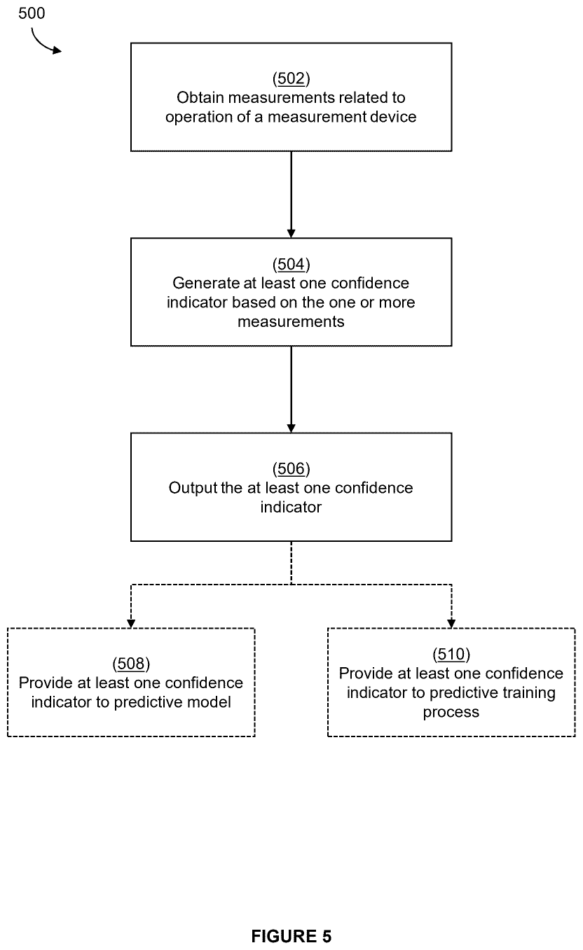

FIG. 5 shows a method 500 according to an aspect of the present disclosure.

The method 500 comprises the steps of obtaining 502 measurements related to operation of a device, generating 504 at least one confidence indicator based on the one or more measurements, and outputting 506 the at least one confidence indicator. The method 500 further comprises the optional steps of providing 508 the at least one confidence indicator to a predictive model and providing 510 the at least one confidence indicator to a predictive model training process.

At the step of obtaining 502, one or more measurements related to operation of a device during generation, by the device, of a digital output signal that is dependent on an input signal.

In one example implementation, the input signal is an analog signal and the device is arranged to generate the digital output signal from the analog input signal. As such, the device may comprise components and/or processing circuitry such as an analog front end, an analog to digital converter (ADC), and signal processing circuitry. The analog input signal can be indicative of one or more of: a temperature; a pressure; a humidity ; a light intensity; an audio signal; and/or a motion signal. The analog input signal can also or instead be indicative of one or more of: a weight; a strain; a distance; a proximity; a position; a level; a vision; a force; a flow rate; a gas concentration; a vital sign; a voltage; a current; a speed; an acceleration. An example device is shown by the measurement device 200 of FIG. 2A and is described in more detail above.

In another example implementation, the input signal may be a digital signal that is processed by the device to generate the digital output signal. For example, the device may be a digital signal processor, a digital signal controller, or the like.

At the step of generating 504, at least one confidence indicator is generated based on the one or more measurements. The at least one confidence indicator is indicative of a reliability of the digital output signal.

The confidence indicator is a value (e.g., a status bit, an alphanumerical value, a numerical value; and/or a vector of values) characteristic of a reliability of the digital output signal generated by the device. The confidence indicator can thus be used by a downstream process, system, model, or component to quantify or assess the quality, reliability, fidelity, and/or accuracy of the digital output signal.

The one or more measurements can comprise an interference signal (e.g., an electromagnetic interference signal) extracted from an intermediate digital output signal generated by the device as part of generating the digital output signal. Example electromagnetic interference signals include a power line interference signal and an out-of-band interference signal. The one or more measurements can further comprise a measurement of DC offset in an AC signal, an electromagnetic interference measurement, an electrical overstress measurement, a high frequency interference on power supply rails measurement, an input common mode voltage change measurement, a supply voltage fluctuation measurement, a clock frequency fluctuation measurement, a clock jitter level measurement, a reference voltage fluctuation measurement, a temperature measurement, a humidity measurement, a mechanical stress measurement, a vibration measurement, a noise measurement, and/or a mission profile measurement.

In one example, the confidence indicator is indicative of multiple measurements combined and represented as a single value. In another example, the second signal processing circuit generates multiple confidence indicators to indicate different aspects of the digital output signal. These confidence indicators can be sent individually or as a vector of values.

The method 500 may further comprise the steps of comparing (not shown) the confidence indicator to a predefined threshold or criterion and, if the confidence indicator meets the predefined threshold or criterion, triggering (not shown) an interrupt. For example, if the confidence indicator is generated from electrical overstress measurements, then when the value of the confidence indicator exceeds normal operating limits (e.g., is indicative of a power surge), then an interrupt may be triggered which stops operation of the measurement device (and/or other devices that receive the interrupt).

At the step of causing 506, output of the digital output signal and the at least one confidence indicator is caused.

The digital output signal and the at least one confidence indicator is output to one or more other devices, systems, networks, or users using one or more communication protocols such as Ethernet, Wi-Fi, Bluetooth, or the like.

At the optional step of providing 508, the digital output signal and the at least one confidence indicator are provided to a predictive model for predicting a value based on the digital output signal and the at least one confidence indicator.

At the optional step of providing 510, the digital output signal and the at least one confidence indicator are provided to a training process for training a predictive model using the digital output signal and the at least one confidence indicator.

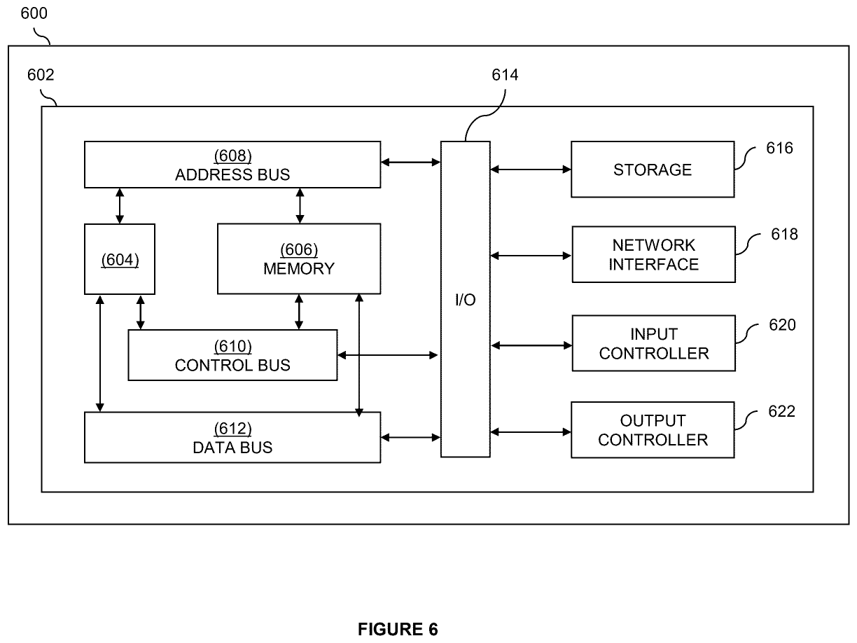

FIG. 6 shows an example computing system. Specifically, FIG. 6 shows a block diagram of an embodiment of a computing system according to example embodiments of the present disclosure.

Computing system 600 can be configured to perform any of the operations disclosed herein such as, for example, any of the operations discussed with reference to the functional units (or modules) described in relation to FIGS. 1-4. Computing system includes one or more computing device(s) 602. Computing device(s) 602 of computing system 600 comprise one or more processors 604 and memory 606. One or more processors 604 can be any general-purpose processor(s) configured to execute a set of instructions. For example, one or more processors 604 can be one or more general-purpose processors, one or more field programmable gate array (FPGA), and/or one or more application specific integrated circuits (ASIC). In one embodiment, one or more processors 604 include one processor. Alternatively, one or more processors 604 include a plurality of processors that are operatively connected. One or more processors 604 are communicatively coupled to memory 606 via address bus 608, control bus 610, and data bus 612. Memory 606 can be a random-access memory (RAM), a read only memory (ROM), a persistent storage device such as a hard drive, an erasable programmable read only memory (EPROM), and/or the like. Computing device(s) 602 further comprise I/O interface 614 communicatively coupled to address bus 608, control bus 610, and data bus 612.

Memory 606 can store information that can be accessed by one or more processors 604. For instance, memory 606 (e.g., one or more non-transitory computer-readable storage mediums, memory devices) can include computer-readable instructions (not shown) that can be executed by one or more processors 604. The computer-readable instructions can be software written in any suitable programming language or can be implemented in hardware. Additionally, or alternatively, the computer-readable instructions can be executed in logically and/or virtually separate threads on one or more processors 604. For example, memory 606 can store instructions (not shown) that when executed by one or more processors 604 cause one or more processors 604 to perform operations such as any of the operations and functions for which computing system 600 is configured, as described herein. In addition, or alternatively, memory 606 can store data (not shown) that can be obtained, received, accessed, written, manipulated, created, and/or stored. The data can include, for instance, the data and/or information described herein in relation to FIGS. 1 to 4. In some implementations, computing device(s) 602 can obtain from and/or store data in one or more memory device(s) that are remote from the computing system 600.

Computing environment 600 further comprises storage unit 616, network interface 618, input controller 620, and output controller 622. Storage unit 616, network interface 618, input controller 620, and output controller 622 are communicatively coupled to the central control unit via I/O interface 614.

Storage unit 616 is a computer readable medium, preferably a non-transitory computer readable medium, comprising one or more programs, the one or more programs comprising instructions which when executed by the one or more processors 604 cause computing environment 600 to perform the method steps of the present disclosure. Alternatively, storage unit 616 is a transitory computer readable medium. Storage unit 616 can be a persistent storage device such as a hard drive, a cloud storage device, or any other appropriate storage device.

Network interface 618 can be a Wi-Fi module, a network interface card, a Bluetooth module, and/or any other suitable wired or wireless communication device. In an embodiment, network interface 618 is configured to connect to a network such as a local area network (LAN), or a wide area network (WAN), the Internet, or an intranet.

The above illustrative examples of various aspects and implementations provide an overview for understanding aspects and implementation of the disclosed method. The figures provided herein depict exemplary aspects of the present system and methods and are not intended to limit the scope of the disclosure.

Unless otherwise stated, all technical terms used herein have the same meaning as commonly understand by a person skilled in the art. Singular forms “a”, “an” and “the” include plural references unless the context of the disclosure clearly dictates otherwise. The term “or” is intended to encompass “and/or” unless clearly stated otherwise.

The above illustrative examples of various aspects and implementations refer to prediction models or machine learning models. Even if not expressly stated, a prediction model or machine learning model can be trained using standard training approaches. For example, a standard approach for training a prediction model comprises obtaining relevant training data (e.g., using known data sources, databases, or data sets) and performing cross-validation to train the prediction model on the training data. Cross-validation can involve splitting the training data into K-folds (approximately equal partitions or sets of the training data) and withholding a single fold as a test set and, one by one, using one of the remaining folds as a validation set and the remaining K−2 folds as a training set. The model is then repeatedly trained on the training set using different model hyperparameters and the performance validated on the validation set. Once the best performing hyperparameters are obtained, the model trained according to the best hyperparameters are evaluated on the test set. For training classification models, the cross-validation strategy can be stratified such that the proportion of training instances within each category or class is approximately the same across each fold. Model hyperparameters can be selected using any suitable approach such as grid search or randomized search. Model performance can be estimated using any suitable performance measure and is dependent on the type of model being trained (e.g., mean square error for regression, binary cross entropy for classification, ranking loss for ranking, etc.).

The terminology “coupled” used herein encompasses both a direct connection between two components/devices/systems, and an indirect electrical connection where the two components/devices/system are connected to each other via one or more intermediate components/devices/systems.

All publications, patents, and patent applications mentioned in this specification are herein incorporated by reference to the same extent as if each individual publication, patent, or patent application was specifically and individually indicated to be incorporated by reference.

Some non-limiting examples of the present disclosure include:

### Example 1

A data acquisition device comprising: a first signal processing circuit for coupling to a digital output of an analog to digital converter, ADC, that is arranged to generate a first digital signal based on an analog input signal, the first signal processing circuit being configured to process the first digital signal to generate a second digital signal based on the first digital signal; and a second signal processing circuit for coupling to the digital output of the ADC and configured to: extract an interference signal from the first digital signal; and calculate a confidence indicator based on the interference signal, wherein the confidence indicator is characteristic of a reliability of the second digital signal generated by the first signal processing circuit; wherein the data acquisition device is configured to output the second digital signal and the confidence indicator.

### Example 2

The data acquisition device of example 1 wherein the interference signal comprises any one or more of: an electromagnetic interference signal; a DC offset measurement.

### Example 3

The data acquisition device of example 2 wherein the electromagnetic interference signal comprises any one or more of: a power line interference signal; an out-of-band interference signal.

### Example 4

The data acquisition device of any preceding example wherein the second signal processing circuit is further configured to: compare the confidence indicator to a predefined threshold; and when the confidence indicator meets the predefined threshold, trigger an interrupt.

### Example 5

The data acquisition device of any preceding example wherein the second signal processing circuit is configured to calculate the confidence indicator in response to receiving a request to calculate the confidence indicator.

### Example 6

The data acquisition device of any preceding example wherein the first signal processing circuit is configured to generate the second digital signal by performing any one or more of: filtering the first digital signal; compressing the first digital signal; signal processing the first digital signal.

### Example 7

The data acquisition device of any preceding example wherein the analog input signal is indicative of any one or more of: a temperature; a pressure; a weight; a strain; a distance; a proximity; a position; a level; a vision; a humidity ; a force; a flow rate; a gas concentration; a light intensity; an audio signal; a motion signal; a vital sign; a voltage; a current; a speed; an acceleration.

### Example 8

A method comprising: obtaining, by processing circuitry, one or more measurements related to operation of a device during generation of a digital signal by the device, the digital signal being generated based on an input signal; generating, by the processing circuitry, at least one confidence indicator based on the one or more measurements, wherein the at least one confidence indicator is indicative of a reliability of the digital signal; and causing, by the processing circuitry, output of the digital signal and the at least one confidence indicator.

### Example 9

The method of example 8 wherein the input signal is an analog signal and the digital signal is a digital representation of the analog signal converted by an analog to digital converter and subsequently processed to generate the digital signal.

### Example 10

The method of either example 8 or example 9 wherein the one or more measurements comprise any one or more of: a power line interference measurement; an out-of-band interference measurement; a DC offset measurement; an electromagnetic interference measurement; an electrical overstress measurement; a high frequency interference on power supply rails measurement; an input common mode voltage change measurement; a supply voltage fluctuation measurement; a clock frequency fluctuation measurement; a clock jitter level measurement; a reference voltage fluctuation measurement; a temperature measurement; a humidity measurement; a mechanical stress measurement; a vibration measurement; a mission profile measurement; a noise measurement.

### Example 11

The method of any of example 8 or example 10 wherein the step of causing output comprises: providing, by the processing circuitry, the digital signal and the at least one confidence indicator to a predictive model for predicting a value based on the digital signal and the at least one confidence indicator.

### Example 12

The method of any of example 8 to 11 wherein the step of causing output comprises: providing, by the processing circuitry, the digital signal and the at least one confidence indicator to a training process for training a predictive model using the digital signal and the at least one confidence indicator.

### Example 13

The method of any of example 8 to 12 wherein the step of outputting comprises: comparing the at least one confidence indicator to a predefined threshold; and when the at least one confidence indicator meets the predefined threshold, triggering an interrupt.

### Example 14

The method of any of example 8 to 13 further comprising: receiving, by the processing circuitry, a request for a confidence indicator; wherein the at least one confidence indicator is generated in response to the request being received.

### Example 15

A computer readable medium including instructions which, when executed by processing circuitry of an edge device, cause the edge device to: obtain one or more measurements related to operation of the edge device during generation, by the edge device, of a digital signal that is dependent on an input signal; generate at least one confidence indicator based on the one or more measurements, wherein the at least one confidence indicator quantifies a reliability of the digital signal; and output the digital signal and the at least one confidence indicator.

### Example 16

The computer readable medium of example 15 wherein the input signal is an analog signal.

### Example 17

The computer readable medium of example 16 wherein the digital signal is a digital representation of the analog signal converted by an analog to digital converter (ADC) to an intermediate digital signal and subsequently processed to generate the digital signal.

### Example 18

The computer readable medium of example 17 further including instructions which, when executed by processing circuitry of the edge device, cause the edge device to: generate, using a signal processor, the digital signal from the intermediate digital signal generated by the ADC.

### Example 19

The computer readable medium of either of example 17 or 18 wherein the one or more measurements include any one or more of: a power line interference measurement extracted from the intermediate digital signal; an out-of-band interference measurement extracted from the intermediate digital signal; a DC offset measurement in an AC signal extracted from the intermediate digital signal; an electromagnetic interference measurement extracted from the intermediate digital signal; an electrical overstress measurement; a high frequency interference on power supply rails measurement; an input common mode voltage change measurement; a supply voltage fluctuation measurement; a clock frequency fluctuation measurement; a clock jitter level measurement; a reference voltage fluctuation measurement; a temperature measurement; a humidity measurement; a mechanical stress measurement; a vibration measurement; a mission profile measurement; a noise measurement.

### Example 20

The computer readable medium of any of example 15 to 19 wherein the at least one confidence indicator is at least one of: a status bit; an alphanumerical value; a numerical value; and/or a vector of values.

What is claimed is:

1. A data acquisition device comprising:
a first signal processing circuit for coupling to a digital output of an analog to digital converter, ADC, that is arranged to generate a first digital signal based on an analog input signal, the first signal processing circuit being configured to process the first digital signal to generate a second digital signal based on the first digital signal; and
a second signal processing circuit for coupling to the digital output of the ADC and configured to:
extract an interference signal from the first digital signal; and
calculate a confidence indicator based on the interference signal, wherein the confidence indicator is characteristic of a reliability of the second digital signal generated by the first signal processing circuit;
wherein the data acquisition device is configured to output the second digital signal and the confidence indicator.

2. The data acquisition device of claim 1 wherein the interference signal comprises any one or more of: an electromagnetic interference signal; a DC offset measurement.

3. The data acquisition device of claim 2 wherein the electromagnetic interference signal comprises any one or more of: a power line interference signal; an out-of-band interference signal.

4. The data acquisition device of claim 1 wherein the second signal processing circuit is further configured to:
compare the confidence indicator to a predefined threshold; and
when the confidence indicator meets the predefined threshold, trigger an interrupt.

5. The data acquisition device of claim 1 wherein the second signal processing circuit is configured to calculate the confidence indicator in response to receiving a request to calculate the confidence indicator.

6. The data acquisition device of claim 1 wherein the first signal processing circuit is configured to generate the second digital signal by performing any one or more of: filtering the first digital signal; compressing the first digital signal; signal processing the first digital signal.

7. The data acquisition device of claim 1 wherein the analog input signal is indicative of any one or more of: a temperature; a pressure; a weight; a strain; a distance; a proximity; a position; a level; a vision; a humidity ; a force; a flow rate; a gas concentration; a light intensity; an audio signal; a motion signal; a vital sign; a voltage; a current; a speed; an acceleration.

8. A method comprising:
obtaining, by processing circuitry, one or more measurements related to operation of a device during generation of a digital signal by the device, the digital signal being generated based on an input signal;
generating, by the processing circuitry, at least one confidence indicator based on the one or more measurements, wherein the at least one confidence indicator is indicative of a reliability of the digital signal; and
causing, by the processing circuitry, output of the digital signal and the at least one confidence indicator.

9. The method of claim 8 wherein the input signal is an analog signal and the digital signal is a digital representation of the analog signal converted by an analog to digital converter and subsequently processed to generate the digital signal.

10. The method of claim 8 wherein the one or more measurements comprise any one or more of: a power line interference measurement; an out-of-band interference measurement; a DC offset measurement; an electromagnetic interference measurement; an electrical overstress measurement; a high frequency interference on power supply rails measurement; an input common mode voltage change measurement; a supply voltage fluctuation measurement; a clock frequency fluctuation measurement; a clock jitter level measurement; a reference voltage fluctuation measurement; a temperature measurement; a humidity measurement; a mechanical stress measurement; a vibration measurement; a mission profile measurement; a noise measurement.

11. The method of claim 8 wherein the step of causing output comprises:
providing, by the processing circuitry, the digital signal and the at least one confidence indicator to a predictive model for predicting a value based on the digital signal and the at least one confidence indicator.

12. The method of claim 8 wherein the step of causing output comprises:
providing, by the processing circuitry, the digital signal and the at least one confidence indicator to a training process for training a predictive model using the digital signal and the at least one confidence indicator.

13. The method of claim 8 wherein the step of causing output comprises:
comparing the at least one confidence indicator to a predefined threshold; and
when the at least one confidence indicator meets the predefined threshold, triggering an interrupt.

14. The method of claim 8 further comprising:
receiving, by the processing circuitry, a request for a confidence indicator;
wherein the at least one confidence indicator is generated in response to the request being received.

15. A non-transitory computer readable medium including instructions which, when executed by processing circuitry of an edge device, cause the edge device to:
obtain one or more measurements related to operation of the edge device during generation, by the edge device, of a digital signal that is dependent on an input signal;
generate at least one confidence indicator based on the one or more measurements, wherein the at least one confidence indicator quantifies a reliability of the digital signal; and
output the digital signal and the at least one confidence indicator.

16. The non-transitory computer readable medium of claim 15 wherein the input signal is an analog signal.

17. The non-transitory computer readable medium of claim 16 wherein the digital signal is a digital representation of the analog signal converted by an analog to digital converter (ADC) to an intermediate digital signal and subsequently processed to generate the digital signal.

18. The non-transitory computer readable medium of claim 17 further including instructions which, when executed by processing circuitry of the edge device, cause the edge device to:
generate, using a signal processor, the digital signal from the intermediate digital signal generated by the ADC.

19. The non-transitory computer readable medium of claim 17 wherein the one or more measurements include any one or more of: a power line interference measurement extracted from the intermediate digital signal; an out-of-band interference measurement extracted from the intermediate digital signal; a DC offset measurement in an AC signal extracted from the intermediate digital signal; an electromagnetic interference measurement extracted from the intermediate digital signal; an electrical overstress measurement; a high frequency interference on power supply rails measurement; an input common mode voltage change measurement; a supply voltage fluctuation measurement; a clock frequency fluctuation measurement; a clock jitter level measurement; a reference voltage fluctuation measurement; a temperature measurement; a humidity measurement; a mechanical stress measurement; a vibration measurement; a mission profile measurement; a noise measurement.

20. The non-transitory computer readable medium of claim 15 wherein the at least one confidence indicator is at least one of: a status bit; an alphanumerical value; a numerical value; and/or a vector of values.
